(19) United States
(12) Patent Application Publication
(10) Pub. No.: US 2012/0056273 A1
(43) Pub. Date: Mar. 8, 2012

(54) SEMICONDUCTOR DEVICE AND METHOD OF MANUFACTURING THE SAME

(75) Inventors: Yuji Ishii, Kagoshima (JP); Yuji Ibusuki, Kanagawa (JP); Hideki Tanaka, Kagoshima (JP); Kentaro Kasai, Kagoshima (JP)

(73) Assignee: SONY CORPORATION, Tokyo (JP)

(21) Appl. No.: 13/219,007

(22) Filed: Aug. 26, 2011

(30) Foreign Application Priority Data
Sep. 3, 2010 (JP) 2010-197916

(51) Int. Cl. H01L 27/088; H01L 21/8232

(52) U.S. Cl. 257/393; 438/279; 257/E27.06; 257/E21.615

(57) ABSTRACT

A semiconductor device includes: a first transistor formed on a semiconductor substrate; and a second transistor formed above the semiconductor substrate with an insulation film interposed therebetween. The first transistor includes a first body region formed on a surface of the semiconductor substrate, and a first source region and a first drain region formed so as to sandwich the first body region, the second transistor includes a semiconductor layer formed on the insulation film, a second body region formed in a part of the semiconductor layer, a second source region and a second drain region formed so as to sandwich the second body region in the semiconductor layer, agate insulation film formed on the body region of the semiconductor layer, and agate electrode formed on the gate insulation film, and the second drain region is disposed on the first body region.

### FIELD

The present disclosure relates to a semiconductor device and a method of manufacturing the same.

### BACKGROUND

A semiconductor device 100 having an SOI structure according to the related art is constructed as shown in FIG. 10. The semiconductor device 100 includes an SOI (silicon on insulator) substrate provided by forming a semiconductor layer made of single crystal silicon (referred to as “SOI layer”) 103 on a support substrate 101 made of silicon (Si) with an insulation layer (hereinafter referred to as “BOX” layer”) 102 interposed between the semiconductor layer and the substrate.

The SOI layer 103 is isolated by device isolation regions 109, and a source region 107 and a drain region 108 are formed in each part of the SOI layer 103 thus isolated. Further, a gate electrode 106 is formed above a body region 104 to serve as a channel between the source and drain regions with a gate insulation film 105 interposed between the body region 104 and the gate electrode 106.

Since the semiconductor device 100 having such a configuration includes the BOX layer 102 provided under the SOI layer 103, the leakage of a current toward the substrate can be suppressed, and the device can therefore operate at a low voltage. The semiconductor device 100 has a parasitic capacity smaller than that of a semiconductor device having a silicon substrate such as a MOS transistor. Therefore, the device has excellent characteristics such as high suitability to operations at a high speed.

However, the body region 104 of the semiconductor device 100 is not electrically connected to anything such as an external power supply, and the region is therefore in a floating state. As a result, holes generated in the body region 104 are accumulated instead of being discharged, and a floating body effect occurs to make operations of the semiconductor device 100 unstable. Consequently, problems arise including a reduction in a withstand voltage between the source region 107 and the drain region 108.

Under the circumstance, for example, JP-A-2002-334996 (Patent Document 1) has disclosed a technique for fixing the potential of the body region 104 at the ground potential as shown in FIG. 11. Such a configuration is used in a semiconductor device disclosed in Patent Document 1 to discharge holes generated in the body region 104. Thus, the reduction in the withstand voltage between the source region 107 and the drain region 108 is suppressed.

### SUMMARY

In the case of the semiconductor device disclosed in Patent Document 1 in which the body region 104 is fixed to the ground, the problem of unstable operations arises when the device is used on an alternating current or when an AC signal is input to the drain region 108. Specifically, when a negative voltage is applied to the drain region 108, a forward current flows from the drain region 108 to the body region 104. Therefore, when the semiconductor device disclosed in Patent Document 1 is used on an alternating current, the body must be in a floating state, which results in a problem in that the reduction in the withstand voltage between the drain region 108 and the source region 107 cannot be suppressed.

An embodiment of the present disclosure is directed to a semiconductor device including a first transistor formed on a semiconductor substrate and a second transistor formed above the semiconductor substrate with an insulation film interposed therebetween. The first transistor includes a first body region formed on a surface of the semiconductor substrate, and a first source region and a first drain region formed so as to sandwich the first body region. The second transistor includes a semiconductor layer formed on the insulation film, a second body region formed in a part of the semiconductor layer, a second source region and a second drain region formed so as to sandwich the second body region in the semiconductor layer, a gate insulation film formed on the body region of the semiconductor layer, and a gate electrode formed on the gate insulation film. The second drain region is disposed on the first body region. The second body region is disposed on the first drain region. A connection layer is formed between the first drain region and the second body region of the insulation film. The second drain region also serves as a gate electrode of the first transistor.

In the semiconductor device according the embodiment of the present disclosure, the first source region may be grounded, and a predetermined voltage is applied to the second drain region to turn the second transistor on and to connect the second body region to the ground through the first body region serving as a channel.

Another embodiment of the present disclosure is directed to a method of manufacturing a semiconductor device including doping a surface region of semiconductor substrate with an impurity to form a first source region and a first drain region, forming an insulation layer on the semiconductor substrate, removing the insulation film on the first drain region to form a connection groove, filling the connection groove with a metal film to form a connection layer, forming a semiconductor layer on the insulation layer, forming a gate insulation film on the semiconductor layer above the connection layer, forming a gate electrode on the gate insulation film, and forming a second source region and a second drain region in the semiconductor layer on both sides of the gate electrode. The second drain region is disposed on a region between the first source region and the first drain region to provide a first transistor and a second transistor. The second drain region of the second transistor also serves as a gate electrode of the first transistor.

In the semiconductor device according to the embodiment of the present disclosure, the first transistor is formed in the semiconductor device; the first drain region of the second transistor is disposed on the channel of the first transistor; and the connection layer is formed between the body region of the insulation film and the second drain region. Thus, the second transistor can be operated by applying a voltage to the first drain region, and the body region can be switched between open and shorted states by the polarity of the voltage applied to the first drain region. As a result, a reduction in the withstand voltage of the semiconductor device can be suppressed without increasing the cell area of the device even when the device is used with an alternating current.

### BRIEF DESCRIPTION OF THE DRAWINGS

FIG. 1 is a schematic view of a sectional structure of a semiconductor device according to an embodiment of the present disclosure;

FIG. 2 is a diagram showing a circuit configuration of the semiconductor device according to the embodiment of the present disclosure;

FIGS. 3A and 3B are illustrations for explaining operations of the semiconductor device according to the embodiment of the present disclosure;

FIG. 4 is a graph showing electrical characteristics of the semiconductor device according to the embodiment of the present disclosure;

FIG. 5A is an illustration showing a step of manufacturing the semiconductor device according to the embodiment of the present disclosure;

FIG. 5B is an illustration of the step subsequent to the step shown in FIG. 5A;

FIG. 5C is an illustration of the step subsequent to the step shown in FIG. 5B;

FIG. 5D is an illustration of the step subsequent to the step shown in FIG. 5C;

FIG. 5E is an illustration of the step subsequent to the step shown in FIG. 5D;

FIG. 5F is an illustration of the step subsequent to the step shown in FIG. 5E;

FIG. 5G is an illustration of the step subsequent to the step shown in FIG. 5F;

FIG. 5H is an illustration of the step subsequent to the step shown in FIG. 5G;

FIG. 5I is an illustration of the step subsequent to the step shown in FIG. 5H;

FIG. 5J is an illustration of the step subsequent to the step shown in FIG. 5I;

FIG. 5K is an illustration of the step subsequent to the step shown in FIG. 5J;

FIG. 5L is an illustration of the step subsequent to the step shown in FIG. 5K;

FIG. 6 is illustrations showing the formation of a contact;

FIG. 7 is a schematic view of a sectional structure of a semiconductor device according to a modification of the embodiment;

FIG. 8 is a diagram for explaining operations of the semiconductor device according to the modification of the embodiment;

FIG. 9A is an illustration showing a step of manufacturing the semiconductor device according to the modification of embodiment;

FIG. 9B is an illustration of the step subsequent to the step shown in FIG. 9A;

FIG. 9C is an illustration of the step subsequent to the step shown in FIG. 9B;

FIG. 9D is an illustration of the step subsequent to the step shown in FIG. 9C;

FIG. 9E is an illustration of the step subsequent to the step shown in FIG. 9D;

FIG. 9F is an illustration of the step subsequent to the step shown in FIG. 9E;

FIG. 9G is an illustration of the step subsequent to the step shown in FIG. 9F;

FIG. 9H is an illustration of the step subsequent to the step shown in FIG. 9G;

FIG. 9I is an illustration of the step subsequent to the step shown in FIG. 9H;

FIG. 9J is an illustration of the step subsequent to the step shown in FIG. 9I;

FIG. 9K is an illustration of the step subsequent to the step shown in FIG. 9J;

FIG. 9L is an illustration of the step subsequent to the step shown in FIG. 9K;

FIG. 10 is a schematic view of a sectional structure of a semiconductor device according to the related art; and

FIG. 11 is a schematic view of a sectional structure of another semiconductor device according to the related art.

### DETAILED DESCRIPTION

Embodiments of the present disclosure will now be described. The following items will be described in the order listed.

### 1. Configuration of Semiconductor Device

2. Method of manufacturing Semiconductor Device

### 3. Modification (Configuration and Manufacturing Method)

### [1. Configuration of Semiconductor Device]

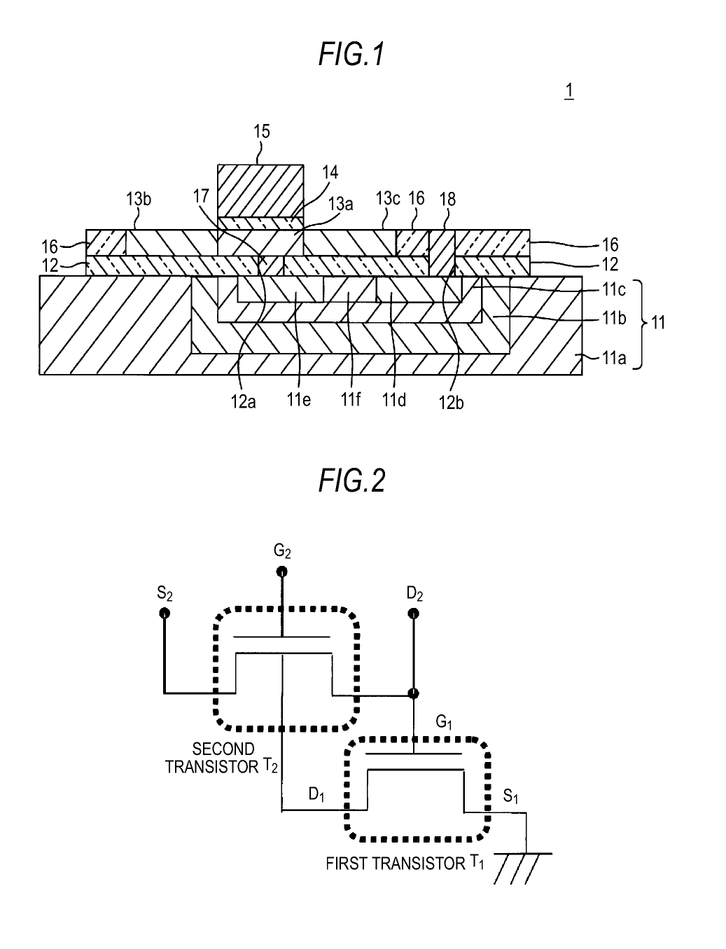

A semiconductor device according to an embodiment of the present disclosure will now be described with reference to the drawings. FIG. 1 is a schematic view of a sectional structure of a semiconductor device 1 according to the present embodiment, and FIG. 2 is a block diagram of the semiconductor device 1 of the present embodiment.

As shown in FIG. 1, the semiconductor device 1 is a MOS transistor having an SOI structure. The semiconductor device 1 includes an SOI substrate provided by forming a semiconductor layer (hereinafter referred to as “SOI layer”) 13 on a semiconductor substrate 11 with an insulation layer (hereinafter referred to as “BOX” layer”) 12 constituted by, for example, a silicon oxide (SiO₂) film interposed between the semiconductor layer and the substrate.

The semiconductor substrate 11 is a silicon (Si) substrate, and the substrate has what is called a triple well structure. Specifically, the semiconductor substrate 11 has a p-sub region 11a doped with a p-type impurity such as boron (B). An n-well region 11b doped with an n-type impurity such as phosphorous (P) or arsenic (As) is formed on the top surface side of the p-sub region 11a. A p-well region 11c doped with a p-type impurity such as boron (B) is formed on the top surface side of the n-well region 11b. In the semiconductor device 11 having a triple well structure as thus described, the p-sub region 11a and the p-well region 11c are isolated from each other by the n-well region 11b.

A first source region 11d and a first drain region 11e doped with an n-type impurity such as phosphorous (P) or arsenic (As) are formed on a top surface of the semiconductor substrate 11 or a top surface of the p-well region 11c with a predetermined gap interposed between the regions. A p-type first body region 11f is formed between the first source region 11d and the first drain region 11e. The first body region 11f serves as a channel between the first source region lid and the first drain region 11e.

As thus described, the semiconductor substrate 11 is formed with the first body region 11f, the first source region lid, the first drain region 11e, and the BOX region 12. The substrate is also formed with a second drain region 13c (serving as a gate electrode) of a second transistor T₂ which will be described later. The second transistors T₂ are isolated by the n-well regions 11b.

The SOI layer 13 is constituted by a film of a semiconductor such as silicon (Si). The SOI layer 13 is formed with a second source region 13b and a second drain region 13c doped with an n-type impurity such as phosphorous (P) or arsenic (As) with a predetermined gap interposed between the regions. A second body region 13a doped with a p-type impurity such as boron (B) is formed in the region between the second source region 13b and the second drain region 13c.

A gate insulation film 14 constituted by, for example, a silicon oxide film (SiO₂) is formed on the second body region 13a. A gate electrode 15 made of polysilicon is formed on the gate insulation film 14.

Second transistors T₂ each constituted by a second body region 13a, a second source region 13b, a second drain region 13c, a gate insulation film 14, and a gate electrode 15 as thus described are formed on the SOI layer 13. The SOI layer 13 is divided by device isolation regions 16 into each second transistor T₂.

A connection hole 12a is formed in the region above the first drain region 11e of the BOX layer 12, and a connection layer 17 made of polysilicon is formed so as to fill the connection hole 12a. The top surface of the connection layer 17 is in contact with the second body region 13a, and the first drain region 11e and the second body region 13a are electrically connected through the connection layer 17.

Further, a connection hole 12b is formed in the region above the first source region 11d of the BOX layer 12, and a connection layer 18 made of polysilicon is formed so as to fill the connection hole 12b. An external voltage is applied to the first source region 11d through the connection layer 18, and the first source region 11d may be grounded.

The semiconductor device 1 according to the present embodiment includes a first transistor T₁ and a second transistor T₂ formed on the semiconductor substrate 11. Since the first drain region 11e of the first transistor T₁ and the second body region 13a of the second transistor T₂ are connected, the second body region 13a can be shorted and opened by turning the first transistor T₁ on and off.

Since the first source region lid of the first transistor T₁ is grounded, the second body region 13a can be grounded by turning the first transistor T₁ on.

Further, since the second drain region 13c of the second transistor T₂ also serves as a gate electrode of the first transistor T₁, the first transistor T₁ can be made to operate by applying a voltage to the second drain region 13c . Therefore, the first transistor T₁ can be made to operate in conjunction with the second transistor T₂, and the second body region 13a can be switched between the shorted and open states by the polarity of the voltage applied to the second drain region 13c.

In addition, since the first transistor T₁ is formed on the semiconductor substrate 11, the second body region 13a can be shorted and opened without increasing the cell area of the semiconductor device 1.

A circuit configuration and electrical characteristics of the semiconductor device 1 having such a configuration will now be described.

A circuit configuration of the semiconductor device 1 according to the present embodiment is shown in FIG. 2. As shown in FIG. 2, the semiconductor device 1 according to the present embodiment includes the first transistor T₁ and the second transistor T₂. A drain D₁ of the first transistor T₁ of the semiconductor device 1 is connected to a gate G₂ of the second transistor T₂. A drain D₂ of the second transistor T₂ is connected between a source S₁ of the first transistor T₁ and the drain D₁ of the transistor (the body region described above).

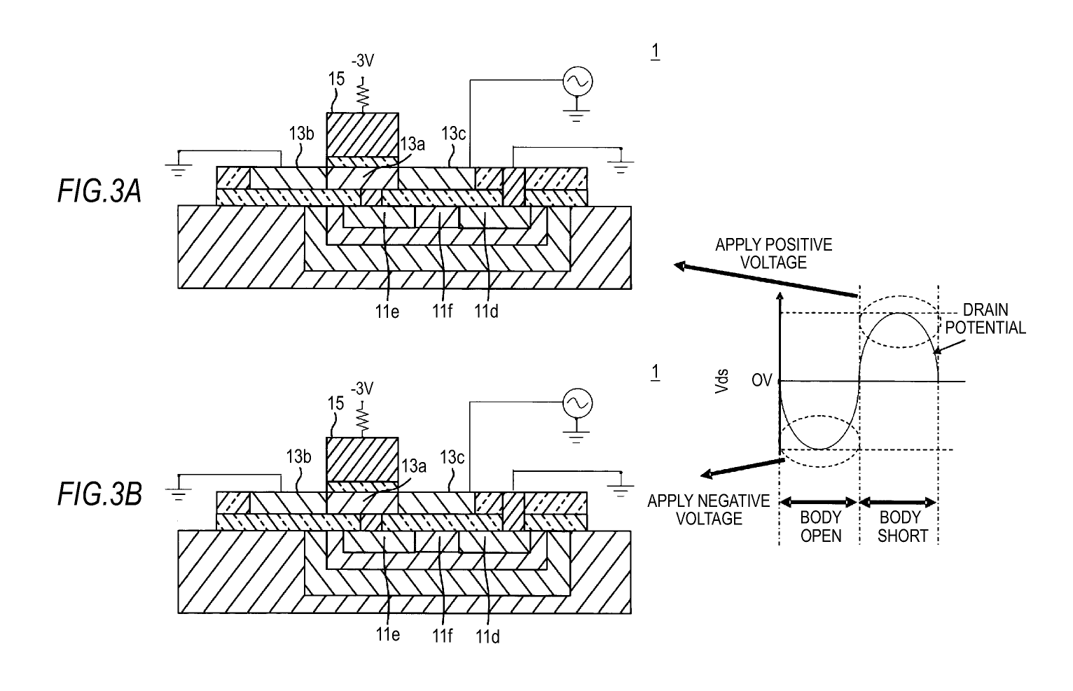

Operations of the semiconductor device 1 according to the present embodiment will now be described. FIGS. 3A and 3B are illustrations showing operations of the semiconductor device 1 according to the present embodiment. As shown in FIG. 3A, when a positive voltage is applied to the second drain region 13c of the second transistor T₂ (i.e., the gate electrode of the first transistor T₁) of the semiconductor device 1, the first transistor T₁ is turned on, and the second body region 13a is shorted. As a result, the second body region 13a is grounded through the first body region 11f which serves as a channel of the first transistor T₁, and holes generated by impacted ions are discharged through the ground instead of being accumulated in the second body region 13a.

As shown in FIG. 3B, when a negative voltage is applied to the second drain region 13c of the second transistor T₂, the first transistor T₁ is turned off, and the second body region 13a is opened. As a result, the potential of the second body region 13a enters a floating state in which no voltage is applied from outside. At this time, a negative voltage (e.g., a voltage of −3 V) is applied to the gate of the first transistor T₁ (i.e., the second drain region 13c), and the source S₁ of the transistor is grounded. The second source region 13b of the second transistor T₂ is grounded.

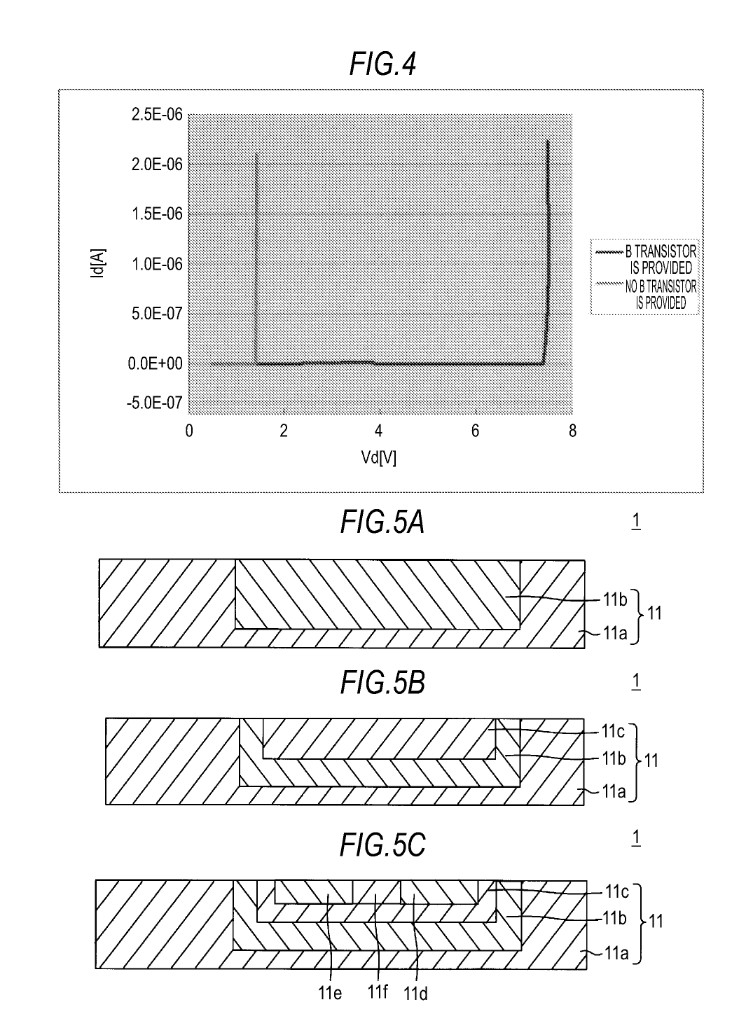

Electrical characteristics of the semiconductor device 1 according to the present embodiment will now be described. FIG. 4 is a graph showing electrical characteristics of the semiconductor device 1 according to the present embodiment. As shown in FIG. 4, when a voltage of about 8 V is applied to the second drain region 13c of the semiconductor device 1 which has the first transistor T₁, a current flows between the second drain region 13c and the second body region 13a. On the contrary, in the case of a semiconductor device according to the related art which does not have a first transistor T₁ as thus described, a current flows between a drain region and a body region when a voltage of about 2 V is applied to a drain region of the semiconductor device. Thus, the semiconductor device 1 has an improved withstand voltage attributable to the provision of the first transistor T₁ because holes are not accumulated in the second body region 13a and a parasitic bipolar operation attributable to holes is unlikely to occur.

### [2. Method of Manufacturing Semiconductor Device]

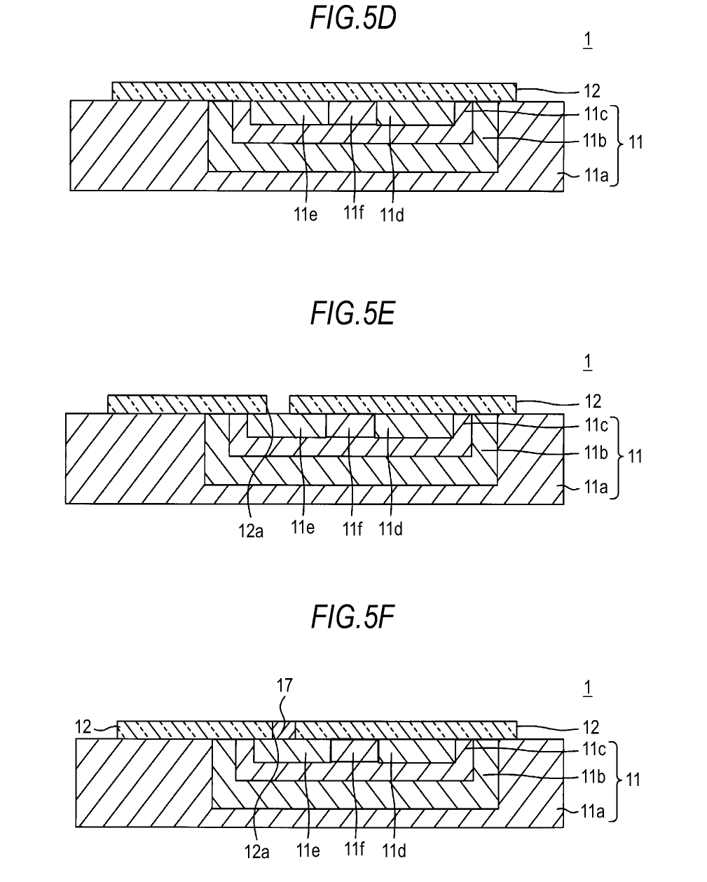

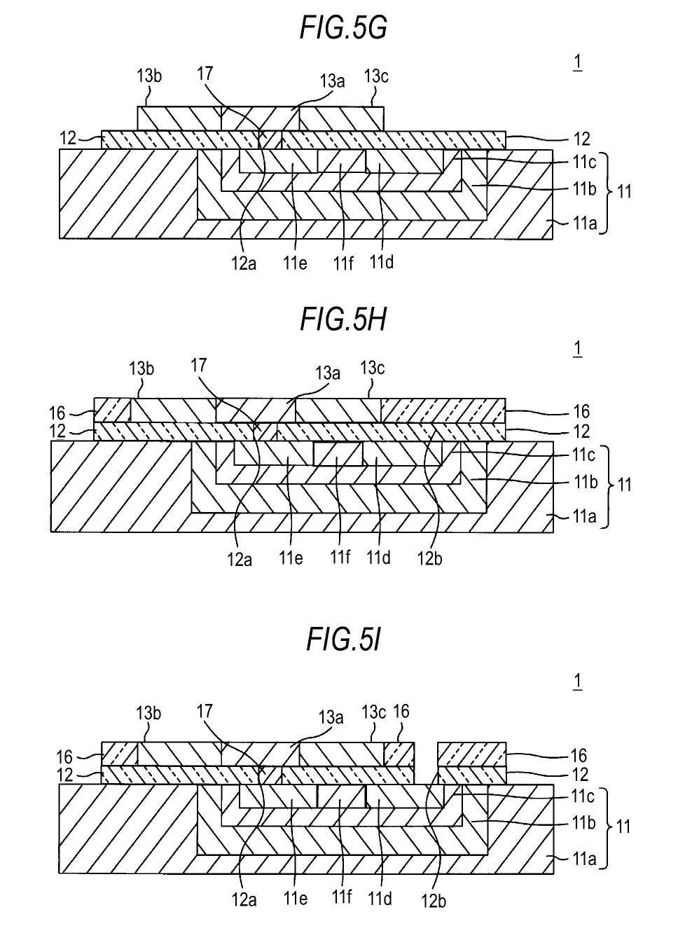

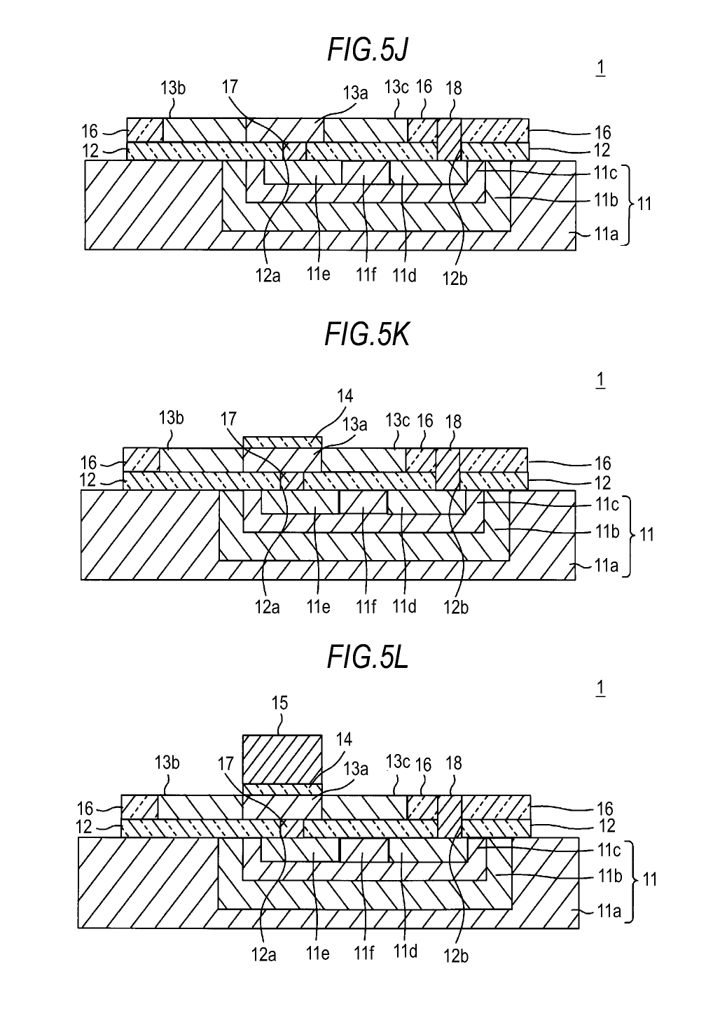

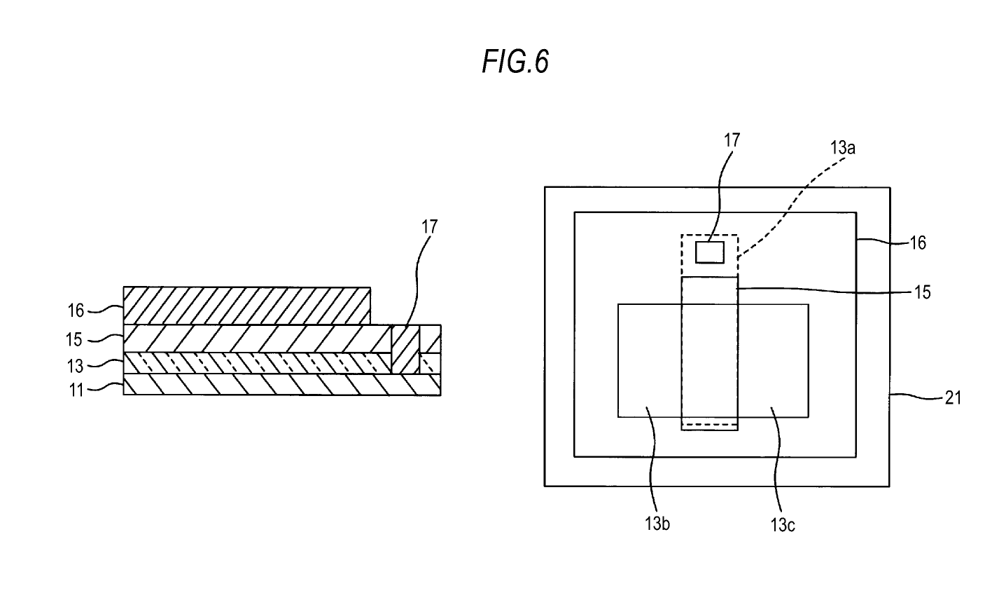

A method of manufacturing the semiconductor device 1 will now be described with reference to FIGS. 5A to 5L and FIG. 6.

As shown in FIG. 5A, for example, ion implantation is carried out on a semiconductor substrate 11 made of silicon (Si) doped with a p-type impurity such as boron (B) to dope a predetermined region of the substrate 11 with an n-type impurity such as phosphorous (P) or arsenic (As) to form an n-well region 11b. Then, the semiconductor substrate 11 excluding the n-well region 11b constitutes a p-sub region 11a.

Next, as shown in FIG. 5B, ion implantation is carried out to dope a predetermined part of the n-well region 11b with a p-type impurity such as boron (B), whereby a p-well region 11c is formed.

Next, as shown in FIG. 5C, ion implantation is carried out to dope predetermined parts of the p-well region 11c on the top side thereof with an n-type impurity such as phosphorous (P) or arsenic (As), whereby a first source region 11d and a first drain region 11e are formed.

Next, as shown in FIG. 5D, a bonding process is performed to form a BOX layer 12 constituted by a silicon oxide (SiO₂) film on the semiconductor substrate 11 selectively. While the BOX layer 12 is formed on the semiconductor substrate 11 using a bonding process in the present embodiment, the present disclosure is not limited to such a process. For example, a SIMOX process may alternatively be used, the process including the steps of implanting oxygen ions in the semiconductor substrate 11 and conducting a thermal treatment thereafter to form a BOX layer 12 in the semiconductor substrate 11. Alternatively, an oxide film may be formed on the surface of the semiconductor substrate 11, and an SOI film 13 may be formed utilizing epitaxial growth.

Next, as shown in FIG. 5E, a connection hole 12a is formed by removing a part of the BOX layer 12 located above the first drain region 11e selectively using photolithography and etching. Next, as shown in FIGS. 5F and 6, a polysilicon film is deposited in the connection hole 12a using a CVD (chemical vapor deposition) process to form a connection layer 17 in the hole.

Next, as shown in FIG. 5G, a polysilicon film doped with a p-type impurity such as boron (B) is selectively deposited on the BOX layer 12 using a CVD process to form an SOI layer 13. Next, ion implantation is carried out to dope predetermined parts of the SOI layer 13 with an n-type impurity such as phosphorous (P) or arsenic (As) to form a second source region 13b and a second drain region 13c. At this time, a region between the second source region 13b and the second drain region 13c constitutes a second body region 13a.

Next, as shown in FIG. 5H, silicon oxide (SiO₂) films are deposited at both ends of the SOI layer 13 on the BOX layer 12 using a CVD process to form device isolation regions 16.

Next, as shown in FIG. 5I, a connection hole 12b is formed by removing the BOX layer 12 and the device isolation regions on the first source region 11d selectively using photolithography and etching.

Next, as shown in FIG. 5J, a polysilicon film is deposited in the connection hole 12b using a CVD process to form a connection layer 18.

Next, as shown in FIG. 5K, a silicon oxide (SiO₂) film is deposited on the second body region 13a using a CVD process to form a gate insulation film 14.

Next, as shown in FIG. 5L, a polysilicon film is deposited on the gate insulation film 14 using a CVD process to form a gate electrode 15.

Through the above-described steps, a second transistor T₂ can be formed in the semiconductor substrate 11, and the second body region 13a of the second transistor T₂ and the first source region 11d of the first transistor T₁ can be electrically connected. Further, the second drain region 13c of the first transistor T₁ can be formed such that it will also serve as a gate of the second transistor T₂.

### [3. Modification (Configurations and Manufacturing Method)]

A modification of the above-described embodiment will now be described.

According to the present modification, a source region of a B transistor as seen in the semiconductor device of the above-described embodiment is formed in an n-well region. A feature that is identical between the above-described embodiment and the present modification will be indicated by the same reference numeral and will not be described.

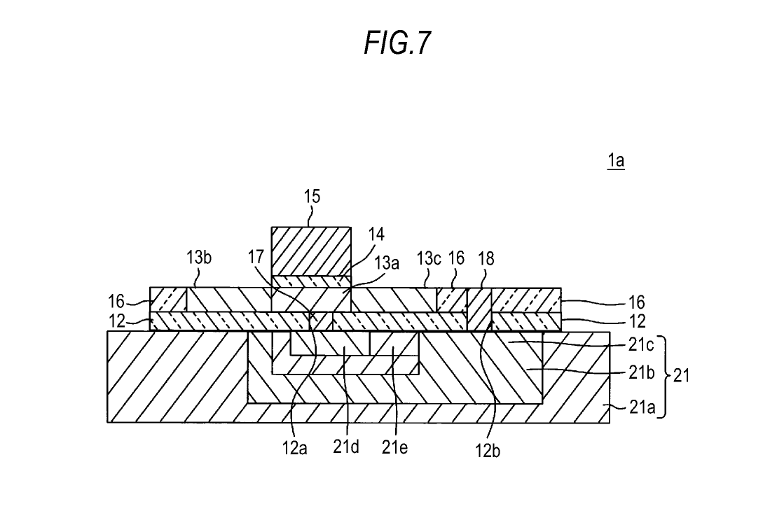

FIG. 7 is a schematic view of a sectional structure of a semiconductor device 1a according to the present modification. As illustrated, the semiconductor device 1a includes a semiconductor substrate 21 on which a first source region (not shown) is formed above an n-well region 21b.

The semiconductor substrate 21 is formed with a p-sub region 21a, a p-well region 21c formed on the p-sub region 21a, and an n-well region 21b isolating the p-sub region 21a and the p-well region 21c.

A first drain region 21d is formed on a top surface of the semiconductor substrate 21, i.e., a top surface of the p-well region 21c. A top part of the n-well region 21b serves as a first source region (not shown). A p-type first body region 21e is formed between the first source region and the first drain region 21d.

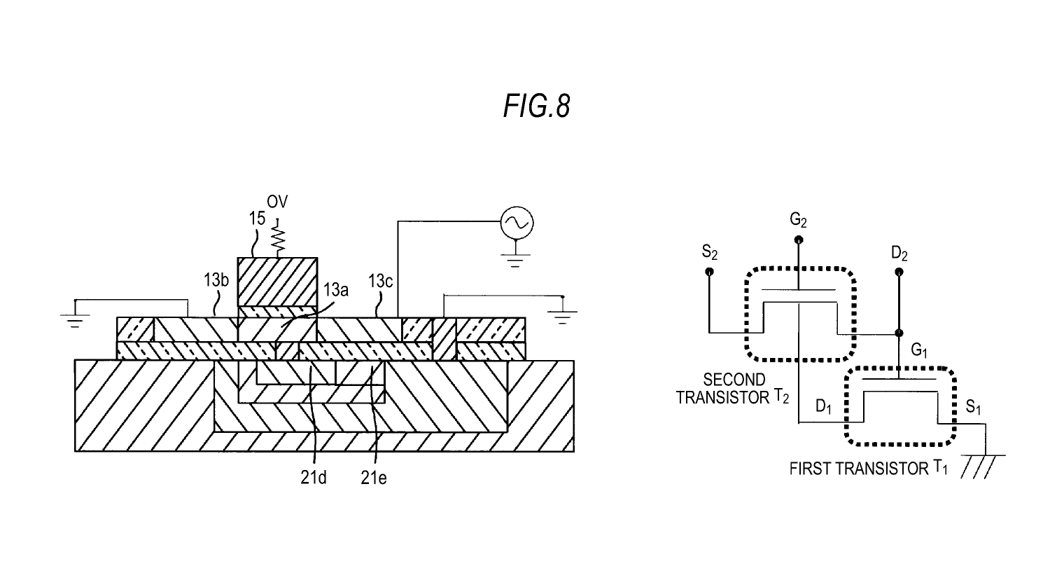

Operations of the semiconductor device 1a according to the present modification will now be described. FIG. 8 is illustrations for explaining operations of the semiconductor device 1a according to the present modification. As shown in FIG. 8, a source S₁ of a first transistor T₁ of the semiconductor device 1a is grounded, and a source S₂ of a second transistor T₂ of the device is grounded. A voltage of 0 V is applied to a gate G₂ of the second transistor, and a predetermined AC voltage is applied to a drain D₂ of the transistor to cause the semiconductor device 1a to operate.

A positive voltage is applied to a drain D₁ of the first transistor T₁ to turn the semiconductor device 1a off. Thus, the second transistor T₂ is turned on, and a second body region 13a of the first transistor T₁ is grounded. A negative voltage is applied to the drain D₁ of the first transistor T₁ to turn the semiconductor device 1a off. Thus, the second transistor T₂ is turned off, and the second body region 13a of the first transistor T₁ becomes open.

As thus described, in the semiconductor device 1a according to the present modification, the second transistor T₂ can be switched between on- and off-states by changing the polarity of the voltage applied to the drain D₁ of the first transistor T₁. Similarly, the second body region 13a of the first transistor T₁ can be switched between open and shorted states. The second body region 13a can be grounded when the semiconductor device 1a is turned off, and a reduction in the withstand voltage can therefore be suppressed. On the contrary, the second body region 13a can be put in the open state when the semiconductor device 1a is turned off, and the potential of the second body region 13a enters a floating state.

A method of manufacturing a semiconductor device 1a according to the present modification will now be described.

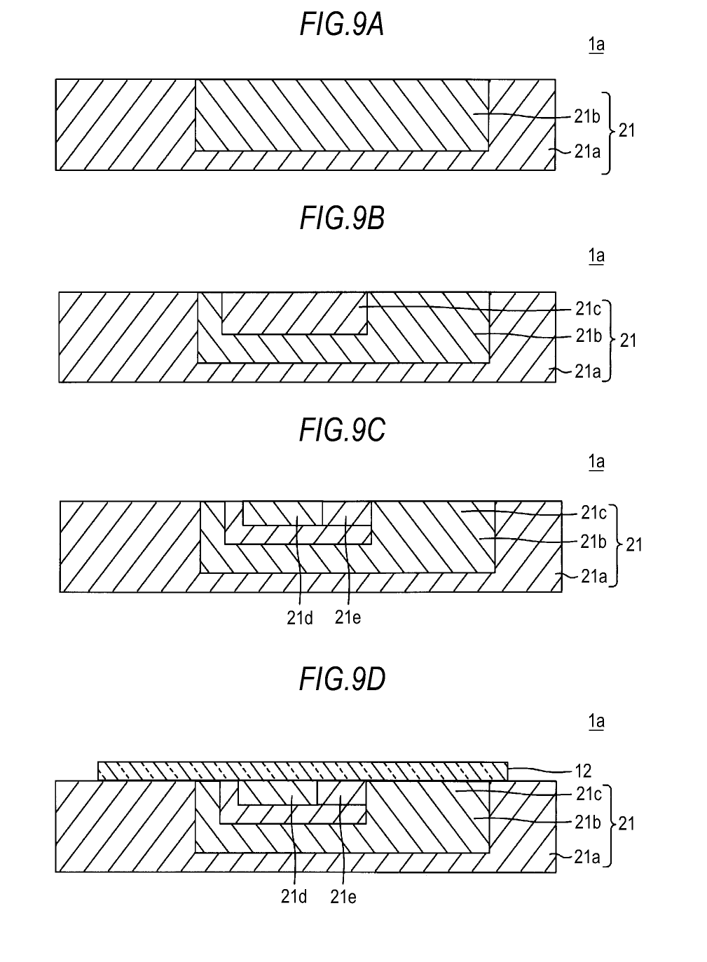

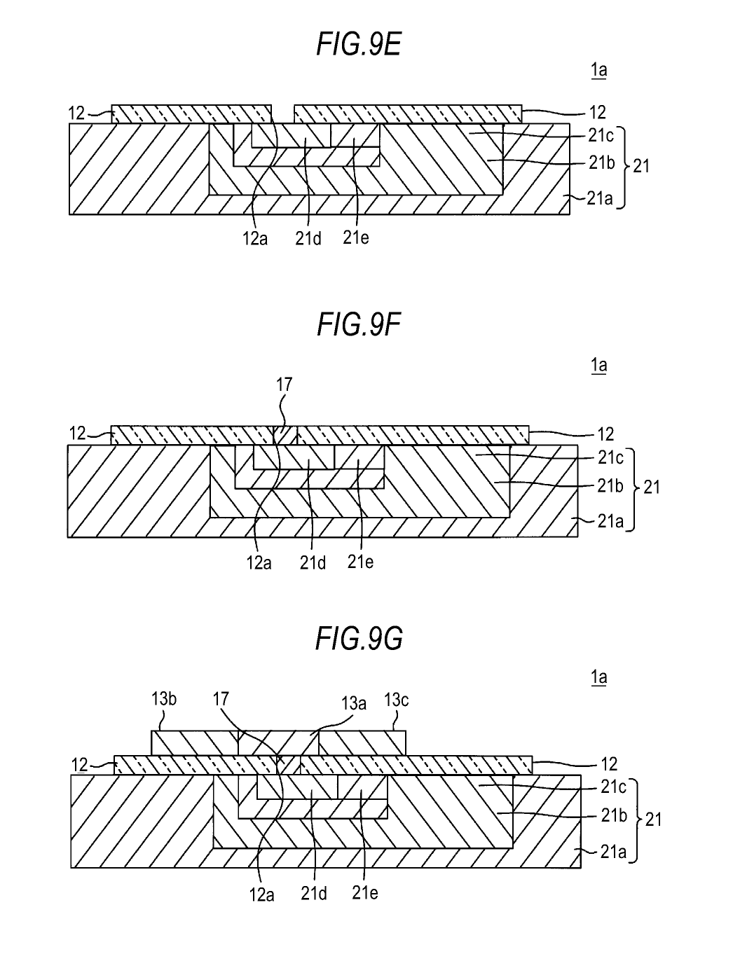

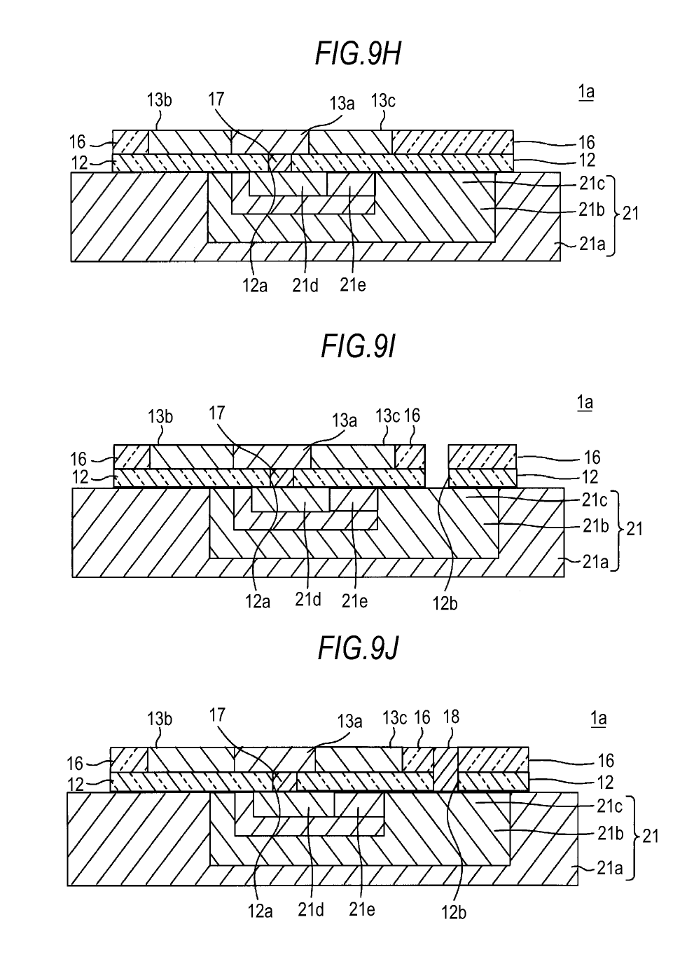

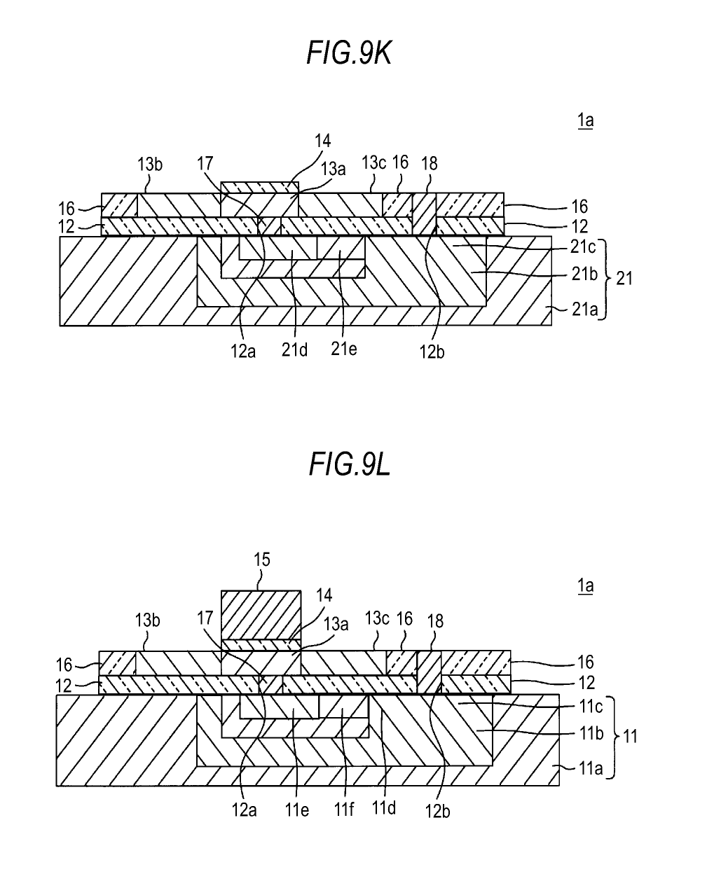

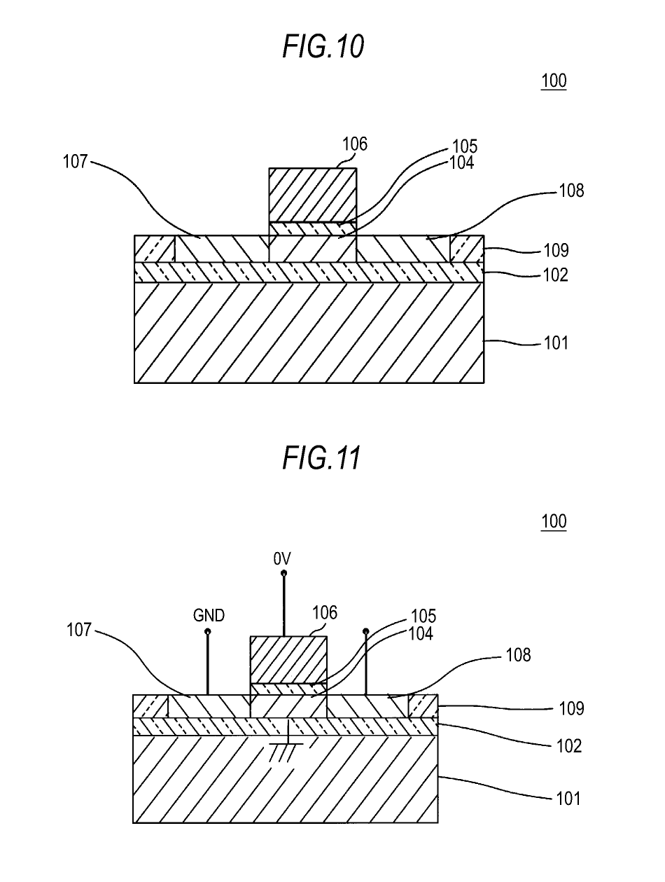

First, as shown in FIG. 9A, ion implantation is carried out on a semiconductor substrate 21 made of silicon (Si) doped with a p-type impurity such as boron (B) to dope a predetermined region of the substrate 21 with an n-type impurity such as phosphorous (P) or arsenic (As) , whereby an n-well region 21b is formed. Then, the semiconductor substrate 21 excluding the n-well region 21b constitutes a p-sub region 21a.

Next, as shown in FIG. 9B, ion implantation is carried out to dope a predetermined part of the n-well region 21b with a p-type impurity such as boron (B), whereby a p-well region 21c is formed.

Next, as shown in FIG. 9C, ion implantation is carried out to dope a predetermined part of the p-well region 21c on the top side thereof with an n-type impurity such as phosphorous (P) or arsenic (As) , whereby a first drain region 21d is formed. A top part of the n-well region 21b serves as a second source region (not shown).

A semiconductor substrate 21 is formed through the steps described above and illustrated in FIGS. 9A to 9C. A first transistor T₁ is formed by steps shown in FIGS. 9D to 9L on the semiconductor substrate 21 formed at the steps described above with a BOX layer 12 interposed between the substrate and the transistor. Thus, a semiconductor device 1a according to the present modification is fabricated. The steps shown in FIGS. 9D to 9L will not be described because they are similar to the steps described above and illustrated in FIGS. 5D to 5L.

Thus, a semiconductor device 1a similar in operations and effects to the above-described semiconductor device 1 is fabricated.

The present disclosure contains subject matter related to that disclosed in Japanese Priority Patent Application JP 2010-197916 filed in the Japan Patent Office on Sep. 3, 2010, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
a first transistor formed on a semiconductor substrate; and
a second transistor formed above the semiconductor substrate with an insulation film interposed therebetween, wherein
the first transistor includes
a first body region formed on a surface of the semiconductor substrate, and
a first source region and a first drain region formed so as to sandwich the first body region,
the second transistor includes
a semiconductor layer formed on the insulation film,
a second body region formed in a part of the semiconductor layer,
a second source region and a second drain region formed so as to sandwich the second body region in the semiconductor layer,
a gate insulation film formed on the body region of the semiconductor layer, and
a gate electrode formed on the gate insulation film,
the second drain region is disposed on the first body region,
the second body region is disposed on the first drain region,
a connection layer is formed between the first drain region and the second body region of the insulation film, and
the second drain region also serves as a gate electrode of the first transistor.

2. The semiconductor device according to claim 1, wherein
the first source region is grounded; and
a predetermined voltage is applied to the second drain region to turn the second transistor on and to connect the second body region to the ground through the first body region serving as a channel.

3. A method of manufacturing a semiconductor device comprising:
doping a surface region of semiconductor substrate with an impurity to form a first source region and a first drain region;
forming an insulation layer on the semiconductor substrate;
removing the insulation film on the first drain region to form a connection groove;
filling the connection groove with a metal film to form a connection layer;
forming a semiconductor layer on the insulation layer;
forming a gate insulation film on the semiconductor layer above the connection layer;
forming a gate electrode on the gate insulation film; and
forming a second source region and a second drain region in the semiconductor layer on both sides of the gate electrode, wherein
the second drain region is disposed on a region between the first source region and the first drain region to provide a first transistor and a second transistor, the second drain region of the second transistor also serving as a gate electrode of the first transistor.
